(19) United States
(12) Patent Application Publication
(10) Pub. No.: US 2026/0127337 A1
(43) Pub. Date: May 7, 2026

(54) FATIGUE LIFE PREDICTION METHOD OF TURBINE BLADE BASED ON LOGIC CONSTRAINT-ENHANCED SYMBOLIC REGRESSION

(71) Applicant: ZHEJIANG UNIVERSITY, Hangzhou (CN)

(72) Inventors: Yiming ZHANG, HANGZHOU (CN); Pei LI, HANGZHOU (CN); Shuyou ZHANG, HANGZHOU (CN)

(21) Appl. No.: 19/215,173

(22) Filed: May 21, 2025

(30) Foreign Application Priority Data
Nov. 4, 2024 (CN) 2024115539418

(51) Int. Cl. G06F 30/23; G06F 30/27

(52) U.S. Cl. CPC G06F 30/23; G06F 30/27

(57) ABSTRACT

A fatigue life prediction method of a turbine blade based on logic constraint-enhanced symbolic regression, includes: constructing a symbol library based on a turbine blade fatigue test dataset; performing dimensionless preprocessing on input variables in the library; constructing a logic constraint-enhanced symbolic regression model with a reinforcement learning module with an RNN as a carrier and a logic constraint rule module, selecting a node from the library to construct expressions, and selecting an expression with best fitting effect as a prediction formula by using a real fatigue test benchmark; guiding the node selection and optimization of the constructed expression structure, and applying a logic constraint rule in the selected node; and obtaining basic mechanical property parameters of a dangerous part under different working conditions, which are used as an input of the fatigue life prediction formula, and outputting a fatigue life cycle number to predict turbine blade fatigue life.

### TECHNICAL FIELD

The present invention relates to the technical field of fatigue life prediction of aero-engine turbine blades, and in particular relates to a fatigue life prediction method of a turbine blade based on logic constraint-enhanced symbolic regression.

### BACKGROUND TECHNOLOGY

As a key component of an aero-engine, a fatigue life of a turbine blade directly affects safety and reliability of an aircraft. An operating environment of the aero-engine has typical “three high” characteristics, namely a high temperature, a high pressure, and a high speed. There are various forms of blade failures, comprising a fatigue failure, a creep failure, and a high-temperature damage, etc. A fatigue damage caused by alternating loads is one of the most common failure types of blade structures. Due to a complex failure mechanism of a key component and a tiny crack, it is difficult to detect a defect such as a tiny crack on the blade even through a regular inspection. Therefore, an ability to conveniently and accurately predict the fatigue life of the blade has gradually become a focus of attention in both academia and industry. Currently, there are various methods for predicting the fatigue life of the blade. One of the widely used methods is to analyze historical or real-time key parameters measured by sensors on the blade, such as temperature, stress, strain, and vibration. By conducting a time-series prediction of these key parameters and combining with failure cases, time of the blade failure can be predicted. However, due to shortage of failure cases and data, researchers have gradually attempted to precisely capture an internal relationship between mechanical properties of materials (such as a tensile strength, and ductility) and fatigue properties, so as to establish a more reliable fatigue life prediction model.

Traditional theoretical methods have derived a series of empirical formulas for establishing the relationship between the mechanical properties and the fatigue life, such as a Coffin-Manson equation, an FS model, a WHS model, etc. Although these empirical formulas have a certain degree of universality among different materials, they rely on a large amount of fatigue test data, are difficult to adapt to complex working conditions, and are difficult to achieve a high-precision life prediction for a specific material. For example, the Chinese Patent with publication number CN118013814A discloses a life prediction method of a high temperature gas-cooled turbine blade, which comprises the following steps: S1: establishing a reduced-order equation between overall design parameters of a gas turbine and a temperature value of a blade and a stress field through a deep learning algorithm; S2: obtaining a measured temperature value of the blade and a measured stress field corresponding to an actual working condition of the gas turbine through sensors; S3: correcting the reduced-order equation in step S1 according to the measured temperature value and the measured stress field obtained in step S2; S4: calculating the temperature value of the blade and the stress field based on the corrected reduced-order equation in step S3, and predicting the remaining life of the high temperature gas-cooled turbine blade.

Data-driven machine learning algorithms provide new ideas for the fatigue life prediction. Many studies have shown that powerful and flexible neural networks can accurately capture an influence trend between the mechanical property parameters of materials and the fatigue life, and find model parameters that best match a data set. However, the neural network is essentially a “black box” model, making it difficult to explain a physical meaning of parameters and their internal influence mechanism, and it has poor interpretability. For example, the Chinese Patent with publication number CN116701943A discloses a small-sample turbine blade damage parameter prediction method based on meta-learning, which belongs to the field of fatigue life evaluation and prediction of turbine blades. Combined with load characteristics of each typical position of the turbine blade during a service process, all typical position at different section heights of the turbine blade are regarded as different service tasks; a meta-learning model is utilized to effectively predict damage parameters of each position of the turbine blade under different service time, improve a blade utilization rate, and reduce a use cost; and aiming at a problem that service data of the turbine blade has a typical time-series correlation but a time series is too short, complete time-series samples of each typical position are packaged into a “pseudo sample” to participate in model training by taking an Long Short-Term Memory (LSTM) network as a base model, and while utilizing the meta-learning to solve the small-sample prediction problem, the time-series correlation of the samples is utilized to improve prediction accuracy of the model.

In actual engineering, people tend to use simple expressions that are easy to understand, have strong generalizability, and can be related to physical laws or known theories to reveal an internal relationship among data. Symbolic regression (SR), as a model based on an evolutionary algorithm, aims to generate an interpretable and highly generalizable target expression to describe the internal relationship among the data. The generated explicit formula has advantages of being easy to access and having a low computational cost, and shows great potential in application scenarios where it is necessary to understand a behavior of the model or follow physical laws and simply predict future trends. Existing studies have shown that the symbolic regression overcomes disadvantages of insufficient prediction accuracy of an empirical formula and excessive dependence on prior knowledge. At the same time, compared with a machine learning model, the symbolic regression has higher interpretability and structural simplicity.

Therefore, how to further improve the prediction accuracy by improving the symbolic regression model is currently a research hotspot in this field.

### SUMMARY OF THE INVENTION

The object of the present invention is to provide a fatigue life prediction method of a turbine blade based on logic constraint-enhanced symbolic regression. This prediction method can realize the fatigue life prediction of the turbine blade and improve the prediction efficiency and accuracy of the fatigue life.

The present invention provides the following technical schemes:

A fatigue life prediction method of a turbine blade based on logic constraint-enhanced symbolic regression, wherein the method comprises the following steps:
S1: constructing a symbol library based on a fatigue test dataset of the turbine blade, wherein the symbol library comprises the following nodes: input variables, arithmetic operators, and constants;
S2: performing dimensionless preprocessing on the input variables in the symbol library to obtain a preprocessed symbol library;
S3: constructing a logic constraint-enhanced symbolic regression model, which comprises a reinforcement learning module with a recurrent neural network (RNN) as a carrier and a logic constraint rule module and is configured to select nodes from the preprocessed symbol library to construct a series of expressions; and selecting and then outputting an expression with the best fitting effect as a fatigue life prediction formula by taking a life determined by a real fatigue test as a benchmark, wherein the reinforcement learning module with the RNN as the carrier guides the selection of the node from the symbol library and the optimization of the structure of the constructed expression, and applies a logic constraint rule in the selected node through the logic constraint rule module; and
S4: performing a finite element simulation on a turbine blade model to be tested to obtain basic mechanical property parameters of a dangerous part of the turbine blade under different working conditions, which are used as an input of the fatigue life prediction formula output in step S3, and outputting a fatigue life cycle number of the turbine blade under corresponding working conditions, so as to realize prediction of the fatigue life of the turbine blade.

The technical concept of the present invention lies in: aiming at work of the fatigue life prediction of the turbine blade of an aero-engine or aircraft engine, the present invention builds a logic constraint-enhanced symbolic regression model that uses reinforcement learning to guide the directed generation of the expression, and combines the logical constraint rules to reduce a search space and ensure physical logic rationality of the expression. Specifically, the model comprises: a symbol library serving as a search space for symbol nodes, the reinforcement learning module with the RNN as the carrier, and the logical constraint rules. Each expression is equivalent to a separate binary tree structure, in which each symbol node is derived from the symbol library; according to a current state of the expression, the reinforcement learning module generates selection probabilities for symbols in the symbol library, and probabilistically selects a new node to be added to the expression in combination with the logical constraint rules, thereby constructing a series of complete expressions. A certain proportion of excellent expressions and the corresponding feedback reward values are selected from the constructed expressions to train the RNN network, enabling the RNN to learn excellent structures and improve a learning strategy. Finally, excellent expressions that match a real data set are spontaneously generated and used as the prediction formula for the fatigue life of a blade material.

In step S1, the input variables are the basic mechanical property parameters of the turbine blade, specifically comprising: axial stress σₐ, shear stress τₐ, Young's modulus E, shear modulus G, an axial strain rate εₐ, and a shear strain rate γₐ; and the arithmetic operators comprise an addition operator, a subtraction operator, a multiplication operator, a division operator, a trigonometric function operator, and an exp exponential operator. The symbol library serves as the search space for nodes during a subsequent process of constructing expressions in the model.

In step S2, considering that the input mechanical property parameters usually have physical units, such as MPa, and GPa, in order to unify the physical units on both sides of the expression, the present invention conducts a dimensionless preprocessing on the input variables in the symbol library according to dimension of physical units and the method of empirical formulas, so as to transform the input variables with the physical units into a combined structure with practical physical significance and without physical units; and a specific method is as follows: performing symbolic operations among the input variables with the physical units, and transforming the input variables into σₐ/E, τₐ/G, εₐ and γₐ after the dimensionless preprocessing,

In step S3, the reinforcement learning module with the RNN as the carrier utilizes the RNN to guide the selection of the node and the optimization of the structure of the expression, which is specifically as follows: the RNN generates a selection probability of each node in the symbol library as a selection strategy of reinforcement learning, and each selection behavior has a corresponding feedback reward value, which is related to a fitting effect of the expression; and the RNN generates a batch of expressions, selects an excellent expression therefrom, reinforces a selection behavior related to a high reward value, and guides subsequent batches to generate better expressions; this iterative process continues until the RNN independently select an appropriate node from the symbol library according to an expression state, and the logic constraint-enhanced symbolic regression model generates the expression with the best fitting effect.

The present invention proposes to use the reinforcement learning to train the parameters of the RNN network and guide the node selection process in the expression, so as to generate an expression that precisely matches the data set. Excellent expressions with the lowest Root Mean Square Error (RMSE) and the best fitting effect are selected from each batch of generated expressions, and the actions related to high feedback reward values in the excellent expressions are further reinforced, and eventually, expressions with excellent fitting effects are generated. By comparing with the empirical formula method and typical machine learning methods, the method proposed by the present invention has achieved comparable or even better prediction accuracy, and obtained an explicit prediction formula for the fatigue life, which is convenient for combination with physical laws and theories.

Alternatively, it is understood that a reinforcement learning strategy is adopted to guide the model to select nodes. As the carrier of reinforcement learning, the RNN generates selection probabilities for the nodes in the symbol library according to upper and lower contexts of the expression; some excellent expressions are selected from each batch of expressions to train the parameters of the RNN network; the excellent structures are reinforced with a goal of maximizing the feedback rewards so as to encourage the generation of excellent expressions in a next batch.

In step S3, the logic constraint rule in the logic constraint rule module specifically comprises: tracking the construction of the expressions by using an array (such as an arity array), controlling a length of the expressions, and imposing a strict constraint on a constant operation and function nesting, wherein the logic constraint rule is applied to the selection process of each node in a form of the selection probability, and a negative infinite selection probability is applied to a node type that violates the rule; and an L-BFGS (Limited-memory Broyden-Fletcher-Goldfarb-Shanno) optimization algorithm is applied to determine the optimal value of the constant node.

The present invention reduces the search space of nodes, optimizes the structure and rationality of the expression by imposing the logical constraint rule, which is used to improve structural simplicity and rigor of the generated formula; and ensures the structural and logical effectiveness of the expression.

The array tracking expression construction is specifically as follows: adopting a binary tree structure by the expression, and using an initially empty array to track a suspension situation of tree structure nodes; each time an arithmetic operator node is added, putting the number of child nodes that needs to be suspended in the node into the array; each time an input variable or constant node is added, decreasing the number of child nodes at the end of the array by one, wherein this process is repeated until the array is empty, indicating that the construction of the expressions is completed;
controlling the length of the expressions is specifically as follows: constraining the length of the expressions by limiting the number of arithmetic operator nodes;
imposing a strict constraint on a constant operation is specifically as follows: constraining the number of constant nodes according to complexity of the dataset, and restricting a meaningless constant arithmetic operation; and
imposing a strict constraint on function nesting is specifically as follows: constraining a nesting operation of unary functions.
In step S3, the logic constraint-enhanced symbolic regression model directly outputs the optimal fatigue life prediction formulas for turbine blades made of different materials under different working conditions,

Alternatively, the logic constraint-enhanced symbolic regression model outputs the optimal fatigue life prediction formulas for different materials under a certain working condition; for turbine blades made of the same material, by taking the fatigue life prediction formulas as general structural expressions, and exploring and adjusting the constant nodes in the expressions, the optimal fatigue life prediction formulas for turbine blade materials under different working conditions are obtained.

It should be noted that for different materials under a certain working condition, the working conditions can be the same or different, and there is no specific limitation; and for turbine blades made of the same material, the fatigue life prediction formulas corresponding to different working conditions are structurally universal. Therefore, by retaining the formula structure of the optimal fatigue life prediction formula under a certain working condition and exploring the optimal constant values for other working conditions, the fatigue life prediction formulas for the materials of turbine blades under different working conditions can be obtained.

Further, the output of the logic constraint-enhanced symbolic regression model is the fatigue life prediction formula for different materials under a certain working condition. The fatigue test data sets of commonly used materials GH4169 and TC4 are applied for turbine blades to the prediction method provided by the present invention, general fatigue life prediction formulas for the turbine blades made of the GH4169 material and the TC4 material are specifically as follows:
a general formula for the GH4169 material under different working conditions:

$$ln ( {N}_{f} ) = a + \frac{b ( {ε}_{a} \frac{{τ}_{a}}{G} + c \frac{{τ}_{a}}{G} + d )}{( {ε}_{a} + {γ}_{a} ) ( {ε}_{a} \frac{{τ}_{a}}{G} + c \frac{{τ}_{a}}{G} + d ) + e} ;$$

a general formula for the TC4 material under different working conditions:

$$ln ( {N}_{f} ) = {a}^{′} + {b}^{′} ( \frac{{ε}_{a}}{{c}^{′} - \frac{{τ}_{a}}{G}} + \frac{{σ}_{a}}{E} ) + \frac{{d}^{′}}{{ε}_{a}} ;$$

wherein a, b, c, d, e, a′, b′, c′, and d′ all represent constant values in the general formulas, which vary with different working conditions.

Furthermore, in step S4, the finite element simulation on the turbine blade model can be performed based on a COMSOL® simulation software to simulate a force acting on the blade under the working condition, and then the fatigue life of the blade under the corresponding working condition is predicted.

The present invention also provides a fatigue life prediction device of a turbine blade based on logic constraint-enhanced symbolic regression, comprising a memory and one or more processors, wherein the memory stores executable codes, and when being executed by the one or more processors, the executable codes are used to implement the fatigue life prediction method of a turbine blade based on logic constraint-enhanced symbolic regression described as above.

The present invention also provides a computer-readable storage medium having a program stored thereon, wherein when being executed by a processor, the program is used to implement the fatigue life prediction method of a turbine blade based on logic constraint-enhanced symbolic regression described as above.

Compared with the prior art, the present invention has the following excellent effects:
(1) introduction of logical constraints: the present invention applies the logical constraint rule in the symbolic regression algorithm, which significantly optimizes the search space of nodes, ensuring the rationality of the structure of the generated expression and its compliance with actual physical meanings;
(2) utilization of the deep reinforcement learning to enhance the excellent expressions: the present invention proposes to utilize the reinforcement learning with the RNN as the carrier to guide the training of the node selection strategy, and continuously reinforce the generation of the excellent structures, thereby improving the efficiency and accuracy of generating high quality expressions;
(3) superior application performance: the prediction method provided by the present invention can obtain an explicit expression between the mechanical properties and fatigue properties of materials, thus enabling effective prediction of fatigue life cycles of blade under different working conditions; and compared with traditional empirical formula methods and machine learning models, the present invention demonstrates superior prediction accuracy and interpretability; and
(4) The prediction method provided by the present invention has captured the internal relationship between the mechanical properties of materials and their fatigue life, and has discovered that the structures of the fatigue life prediction formulas corresponding to the same material under different working conditions are universal. Therefore, as an implementation, the proposal of the general formulas can also improve the prediction efficiency of the fatigue life of materials under different working conditions, and meanwhile, reduce the search space of the nodes during the construction of the prediction formula.

With the continuous expansion of the fatigue data set in the future, combining the method proposed in the present invention with the finite element simulation can provide a reliable reference for the life prediction, maintenance and repair of key components in future engineering applications.

### BRIEF DESCRIPTION OF THE DRAWINGS

FIG. 1 is a schematic diagram of the application principle of a logic constraint-enhanced symbolic regression model proposed in the present invention;

FIG. 2 is a comparison chart between predicted values and actual values of a fatigue life of materials obtained by the optimal life prediction formula of GH4169 at 25° C. in the present invention;

FIG. 3 is a comparison chart between predicted values and actual values of a fatigue life of materials obtained by the optimal life prediction formula of GH4169 at 650° C. in the present invention;

FIG. 4 is a comparison chart between predicted values and actual values of a fatigue life of materials obtained by using a verification data set of GH4169 at 25° C. in a ten-fold cross-validation method for an enhanced symbolic regression algorithm;

FIG. 5 is a comparison chart between predicted values and actual values of a fatigue life of materials obtained by using a verification data set of GH4169 at 650° C. in a ten-fold cross-validation method for an enhanced symbolic regression algorithm;

FIG. 6 is a comparison chart between predicted values and actual values of a fatigue life of GH4169 obtained by a Coffin Manson equation in an empirical formula;

FIG. 7 is a comparison chart between predicted values and actual values of a fatigue life of GH4169 obtained by BM in an empirical formula;

FIG. 8 is a comparison chart between predicted values and actual values of a fatigue life of GH4169 obtained by KBM in an empirical formula;

FIG. 9 is a comparison chart between predicted values and actual values of a fatigue life of GH4169 obtained by FS in an empirical formula;

FIG. 10 is a comparison chart between predicted values and actual values of a fatigue life of GH4169 obtained by WHS in an empirical formula;

FIG. 11 is a comparison chart between predicted values and actual values of a fatigue life of GH4169 obtained by MWHS in an empirical formula;

FIG. 12 is a comparison chart between predicted values and actual values of a fatigue life of GH4169 obtained by the enhanced symbolic regression algorithm proposed in the present invention;

FIG. 13 is a comparison chart between predicted values and actual values of a fatigue life of GH4169 obtained by LSTM in a machine learning model;

FIG. 14 is a comparison chart between predicted values and actual values of a fatigue life of GH4169 obtained by SVR in a machine learning model;

FIG. 15 is a comparison chart between predicted values and actual values of a fatigue life of GH4169 obtained by RF in a machine learning model;

FIG. 16 is a comparison chart between predicted values and actual values of a fatigue life of GH4169 obtained by Gradient Boosting in a machine learning model; and

FIG. 17 is a comparison chart between predicted values and actual values of a fatigue life of GH4169 obtained by XGBoost in a machine learning model.

### DETAILED DESCRIPTION OF THE EMBODIMENTS

Herein, implementation examples will be described in detail, and specific example results will be shown in the accompanying drawings. The terms used in the present invention are merely for the purpose of describing particular implementation examples and are not intended to limit the present invention.

A fatigue life prediction method of a turbine blade based on logic constraint-enhanced symbolic regression (RSL) proposed by the present invention is applied to establish fatigue life prediction formulas for commonly used materials GH4169 and TC4 of a turbine blade, and to predict the fatigue life of the blade, so as to verify performance advantages of the method of the present invention. The specific implementations of the present invention will be described more completely and clearly in combination with the accompanying drawings, which specifically comprise the following steps:
Step 1: determining a data set and a symbol library;
Step 1.1: obtaining a data set of a fatigue test of a turbine blade material through the fatigue test of the turbine blade material, which comprises real life values of the material;
Step 1.2: determining a symbol library and output of a logic constraint-enhanced symbolic regression model according to the data set of the fatigue test of the turbine blade material, wherein the symbol library comprises the following nodes: input variables, arithmetic operators, and constants; letting the input variables xᵢ be basic mechanical property parameters of the material, namely, xᵢ=[εₐ, γₐ, σₐ, τₐ, E, G], specifically axial strain εₐ, shear strain γₐ, axial stress σₐ, shear stress τₐ, Young's modulus E, and shear modulus G of the material; the output of the logic constraint-enhanced symbolic regression model is a fatigue life prediction formula; and determining arithmetic operators involved in the model, mainly comprising binary arithmetic operators {+, −, x, ÷} and unary operators {sin, cos, log, exp}, wherein the number of child nodes of the binary arithmetic operators is 2, and the number of child nodes of the unary operators is 1. The symbol library is denoted as {xᵢ, operator, c}, wherein xᵢ represents an input basic mechanical property parameter of the material, operator represents all the arithmetic operators, and c represents a constant node in the expression. The nodes of the expression sequence are all sampled from the symbol library.

### Step 2: Performing Dimensionless Preprocessing on the Input Variables;

Considering that the input mechanical properties usually have physical units, such as MPa, and GPa, in order to unify physical units on both sides of the expression, the present invention introduces dimensionless preprocessing to convert input variables with physical units into a dimensionless variable combination structure that retains actual physical meaning. The input axial stress σₐ is replaced with σₐ/E, and the shear stress τₐ is replaced with τₐ/G. In a stress-strain curve, E corresponds to a slope, which means that σₐ/E physically represents the axial strain. Similarly, τₐ/G represents the shear strain.

### Step 3: Obtaining a Fatigue Life Prediction Formula of the Material Based on the Logic Constraint-Enhanced Symbolic Regression Model;

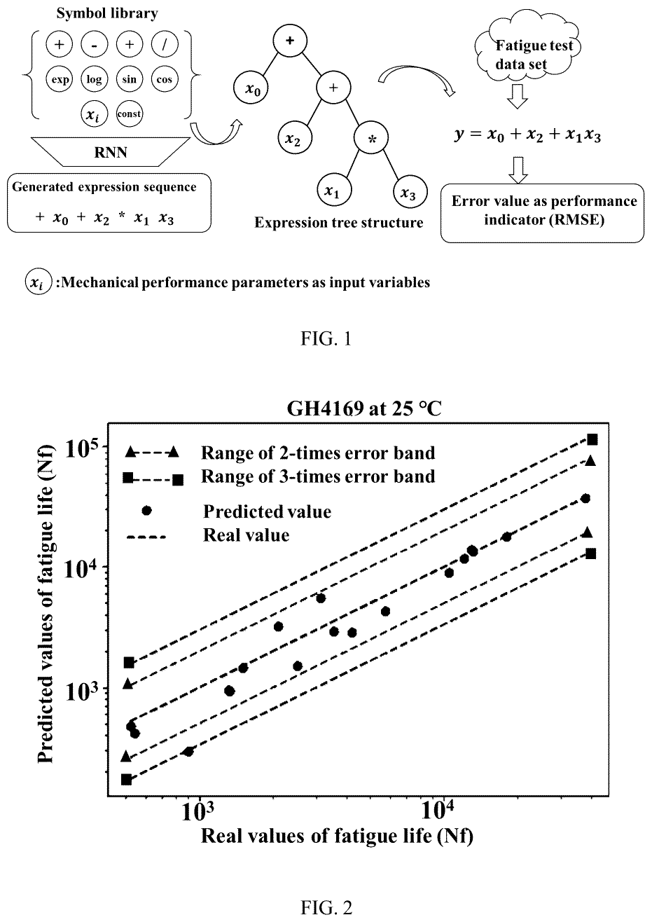

As shown in FIG. 1, constructing the logic constraint-enhanced symbolic regression model, selecting a node from the preprocessed symbol library to construct a series of expressions; and selecting and then outputting an expression with a best fitting effect as a fatigue life prediction formula by taking a life determined by a real fatigue test as a benchmark, wherein the logic constraint-enhanced symbolic regression model comprises a reinforcement learning module with an RNN as a carrier and a logical constraint rule module. The reinforcement learning module with the RNN as the carrier guides selection of nodes from the symbol library, and imposes a logical constraint rule through the logical constraint rule module during the selection of nodes.

The logic constraint-enhanced symbolic regression model adds the logical constraint rule to the selection of nodes in the expression so as to reduce a search space of nodes, optimize structures of the expressions, and ensure rationality of the physical meaning. The logical constraint rule comprises:

(1) Updating an “arity” array to track the progress of construction of expression and ensure the complete construction of the expression: the expression is represented using a binary tree structure; when constructing the tree structure of the expression, an “arity” array that is initially empty is introduced; this array is continuously updated according to a state stateᵢ of the expression and reflects the number of child nodes required for each arithmetic operator node in the tree structure; specifically, when a new arithmetic operator node is introduced, the number of child nodes required by this arithmetic operator node is added to the end of the “arity” array; when adding a constant node or an input variable node, one is subtracted from the value at the end of the array; when the value at the end is zero, it is removed, and then continue to subtract one from the new value at the end. This step is repeated until the array becomes an empty array, indicating that the construction of the expressions is completed.

(2) Controlling the length of the expression by the number of arithmetic operator nodes: considering diversity of expression forms in the present invention, the model alternately generates the arithmetic operator nodes and the constant nodes, which may lead to the complete construction of the expression tree before reaching the specified length; and to avoid this situation, the present invention proposes that if the number of arithmetic operator nodes has not reached the pre-set length value and all values in the “arity” array are 1, then an arithmetic operator node is forcibly selected as a next new node.

(3) Constant operation suppression mechanism: in most cases, a result of a constant operation may be replaced by a constant value; considering simplicity of the expression, the present invention prohibits all child nodes under an arithmetic operator node from being constants, such as forms like 3.14+2; meanwhile, the number of constant nodes has a significant impact on the expression structure; if the number of constant nodes is not limited, the algorithm often excessively explores constants to replace variable parameters; and therefore, the present invention sets a threshold for the number of constant nodes, and this threshold may be adjusted according to a defined length of the expression and the complexity of the data set.

(4) Function nesting control: in actual physical formulas, a nested structure of unary functions is rare and usually has no practical physical meaning; in terms of computational performance, continuous nesting of function operations may lead to a significant expansion of a computational space, especially in a case of exponential nesting; meanwhile, to prevent redundant and meaningless inverse function operations from affecting simplicity, the present invention limits the nested operations of unary functions.

To improve generation efficiency of valid expressions, the present invention applies a constraint rule to the selection process of each node. Regarding the selection probability of each node generated by the RNN, a probability of negative infinity is assigned to nodes that violate the constraint rule. By integrating these two aspects, a suitable new node is selected.

The logic constraint-enhanced symbolic regression model adopts a reinforcement learning strategy to train the network to select nodes. The RNN is a core of node selection. It generates a distribution probability for the nodes in the symbol library, which serves as the selection strategy in the reinforcement learning. In the reinforcement learning, the selection of an action based on a current expression state is determined by a policy function π_{θ}(aₜ|sₜ)

$${π}_{θ} ( {a}_{t} \vert {s}_{t} ) = P ( {a}_{t} \vert {s}_{t} ; θ )$$

wherein sₜ corresponds to the current expression state; aₜ represents a behavior of selecting a next node from the symbol library; and θ represents a weight parameter of the RNN network, which is optimized through training. Selecting a node according to the policy function results in a corresponding action reward. An expected cumulative reward under a given policy may be represented by a state-value function V^{π}(s), which is described by a Bellman Expectation Equation as:

$${V}^{π} ( s ) = {E}_{a - π} [ R ( s , a ) + γ {V}^{π} ( {s}^{′} ) ]$$

wherein s′ is a next state after performing an action a, influence of an expected reward V^{π}(s′) of the next state on the current state may be measured by a discount factor γ, and R(s, a) is an immediate reward corresponding to taking the action a in a state s. A state-action value function Q^{π}(s, a) represents an expected cumulative reward after selecting the action a in the state s; and

$${Q}^{π} ( s , a ) = R ( s , a ) + γ {E}_{{s}^{′} \sim P} [ {V}^{π} ( {s}^{′} ) ]$$

a Q function may be used to evaluate the quality of each action and guide policy optimization. To make the policy function π_{θ} more accurate in the node selection, the parameter θ in the π_{θ} needs to be continuously optimized. The optimization process is achieved through policy gradients, and the policy is updated by maximizing the expected reward J_{θ}:

$${∇}_{θ} J ( θ ) = {E}_{s \sim {π}_{θ} , a \sim {π}_{θ}} [ {∇}_{θ} log {π}_{θ} ( a \vert s ) R ( s , a ) ]$$

wherein ∇_{θ} represents taking the gradient, log π_{θ}(a|s) is a log-probability of the policy function, and its gradient is used to adjust the parameter θ to enhance the selection probability of high-reward actions. In the present invention, the prediction accuracy of the expression is measured by a Root Mean Square Error (RMSE) between a predicted life value and a real life value, and a determination coefficient R². The feedback reward for node selection is defined as a negative value of the RMSE, which encourages the generation of expressions in a direction of reducing the value of the RMSE. When training the network parameters, among each batch of generated expressions, excellent expressions with the lowest RMSE and a best fitting effect are selected for subsequent strengthening of the excellent structures. A calculation method of the predicted life value is as follows: it is obtained by inputting basic mechanical performance parameters of the turbine blade material into the corresponding expression.

Since there is no observable state for selection of a first node of the expression, the present invention counts types and occurrence probabilities of first nodes in a previous batch of excellent expressions, introduces a certain degree of variation, and selects first nodes of expressions in a current batch accordingly, so that the generation of all nodes has a reference strategy.

To determine the values of the constant nodes, the present invention utilizes an L-BFGS optimization algorithm to optimize the constant values and find optimal constant values that minimize a fitting error of the expression. An L-BFGS gradient descent formula is:

$${θ}_{optimal} = arg {min}_{θ} RMSE ( {y}_{t r u e} , {y}_{p r e d} )$$

wherein yₜᵣᵤₑ represents the real fatigue life in the test dataset, y_{pred} represents the fatigue life predicted by the expression, and θₒₚₜᵢₘₐₗ represents the optimal constant value that minimizes the RMSE between the real value and the predicted value of the fatigue life.

The fatigue test datasets of commonly used turbine blade materials GH4169 and TC4 are inputted into the above-mentioned logic constraint-enhanced symbolic regression model. The hyperparameters for the expression structure constraints set with reference to the complexity of the data set are specifically as shown in table 1. On this basis, an overall structural feature such as an expression length is restricted.

In this embodiment, a source of the data set of the fatigue test of the turbine blade material is:

WU Z-R, HU X-T, SONG Y-D. Multiaxial fatigue life prediction for titanium alloy TC4 under proportional and nonproportional loading [J]. International Journal of Fatigue, 2014, 59:170-5;

Wu et al. Evaluation of multiaxial fatigue life prediction criteria for Ni-based superalloy GH4169 [J]. Transactions of the Institution of Mechanical Engineers, Part C: Journal of Mechanical Engineering Science, 2017, 232:095440621770821.

SUN G-Q, SHANG D-G, BAO M. Multiaxial fatigue damage parameter and life prediction under low cycle loading for GH4169 alloy and other structural materials [J]. International Journal of Fatigue, 2010, 32 (7): 1108-1115.

TABLE 1
Hyperparameter setting for overall
structure constraint of expression

| Parameter | N_{size} | N_{epoch} | n_{group} | p₁ | p₂ | l | N_{const} |
|---|---|---|---|---|---|---|---|
| Value | 1300 | 32 | 2 | 0.025 | 0.04 | 10 | 5 |

wherein N_{size} represents the number of expressions generated in each batch, N_{epoch} represents the number of batches, n_{group} represents the number of batches for expanding the number of expressions, p₁ represents a proportion of excellent expressions in initial expansion batches, p₂ represents a proportion of excellent expressions in subsequent batches. In the present invention, the number of expressions in initial 2 batches is expanded from 1300 to 16900 to make forms more diversified. l represents the length of the expression, and N_{const} represents the maximum number of constants in the expression. These hyperparameters provide structural constraints for the expressions and limit the complexity of the expressions. Subsequently, they can be continuously adjusted according to the complexity and scale of the data set.

The present invention uses the RMSE and the determination coefficient R² as a performance evaluation criterion. The RMSE is a measure of difference between the observed values and the real values. The smaller the value, the higher the prediction accuracy. R² ranges from [0, 1]. The closer it is to 0, the worse the fitting degree of the model to the data; the closer it is to 1, the better the fitting degree.

As a first implementation: the output of the logic constraint-enhanced symbolic regression model is the fatigue life prediction formulas for different materials of the turbine blade under different working conditions. Under the structural constraint hyperparameters set in Table 1, the representative and excellent fatigue life prediction formulas output by adjusting the training intensity of the RNN model are as shown in Table 2, wherein N_{f} is the number of fatigue life cycles.

TABLE 2
Representative excellent expression

| | | | | Serial |
|---|---|---|---|---|
| Dataset | Representative excellent formula | RMSE | R² | number |
| GH4169 under 25° C. | $ln ( {N}_{f} ) = 3.148 + \frac{7.171 ( {ε}_{a} \frac{{τ}_{a}}{G} - 0.785 \frac{{τ}_{a}}{G} + 2.74 )}{( {ε}_{a} + {γ}_{a} ) ( {ε}_{a} \frac{{τ}_{a}}{G} - 0.785 \frac{{τ}_{a}}{G} + 2.74 ) - 0.003}$ | 9.8525 × 10² | 0.98766 | (1) |
| | $ln ( {N}_{f} ) = 5.27 + \frac{{γ}_{a} + 11.443}{{ε}_{a} \frac{{τ}_{a}}{G}} - \frac{0.048}{{ε}_{a}^{2} \frac{{τ}_{a}}{G} ( {γ}_{a} + \frac{{τ}_{a}}{G} - 6.81 )}$ | 1.0067 × 10³ | 0.98767 | (2) |
| | $ln ( {N}_{f} ) = 5.259 + \frac{{γ}_{a} + 11.485}{{ε}_{a} \frac{{τ}_{a}}{G}} - \frac{0.051}{{ε}_{a}^{2} \frac{{τ}_{a}}{G} ( {ε}_{a} + \frac{{τ}_{a}}{G} - 6.527 )}$ | 1.0070 × 10³ | 0.98766 | (3) |
| TC4 under 25° C. | $ln ( {N}_{f} ) = 4.2456 + 0.0029 \times ( \frac{{ε}_{a}}{7.126 - \frac{{τ}_{a}}{G}} + \frac{{σ}_{a}}{E} ) + \frac{2.2477}{{ε}_{a}}$ | 4.2178 × 10³ | 0.92622 | (4) |
| | ${N}_{f} = \frac{- 181.472 \frac{{τ}_{a}}{G}}{{ε}_{a} ( - 1.98 {ε}_{a} \frac{{τ}_{a}}{G} + 10.701 {ε}_{a} + \frac{{τ}_{a}}{G} - 5.807 )}$ | 4.4164 × 10³ | 0.91911 | (5) |
| | $ln ( {N}_{f} ) = 5.918 - \frac{6.173}{{γ}_{a}} + \frac{5.178}{{ε}_{a} {γ}_{a}} - \frac{2.827 G}{{( {ε}_{a} {γ}_{a} )}^{2} {τ}_{a}}$ | 4.5838 × 10³ | 0.91285 | (6) |
| GH4169 under 650° C. | $ln ( {N}_{f} ) = 4.8184 + 0.738 {ε}_{a} ( - 0.11 \frac{{ε}_{a} {τ}_{a}}{G} - 0.89 {γ}_{a} + 0.526 )$ | 1.4449 × 10² | 0.99040 | (7) |
| | $ln ( {N}_{f} ) = 4.968 + {ε}_{a} ( \frac{{τ}_{a}}{G} ( 1.391 - {γ}_{a} ) ( {ε}_{a}^{2} - 7.85 {ε}_{a} + 4.207 ) + 1.266 )$ | 1.4531 × 10² | 0.99029 | (8) |
| | $ln ( {N}_{f} ) = 3.925 + 4.257 {ε}_{a} + 4.257 \frac{{τ}_{a}}{G} ( 0.457 {ε}_{a} {γ}_{a}^{2} - 0.885 {ε}_{a} {γ}_{a} + 0.228 )$ | 1.5079 × 10² | 0.98594 | (9) |

It can be seen from Table 2 that under the hyperparameters set in Table 1, the optimal fatigue life prediction formula for GH4169 at 25° C. is formula (1), the optimal fatigue life prediction formula for GH4169 at 650° C. is formula (7), and the optimal fatigue life prediction formula for TC4 at 25° C. is formula (4).

As a second implementation, the output of the logic constraint-enhanced symbolic regression model is the optimal fatigue life prediction formulas for different materials under a certain working condition; for turbine blades made of the same material, by taking the fatigue life prediction formulas as general structural expressions and retaining the specific structure of the expression and exploring and adjusting the optimal values of the constant nodes in the expression, the fatigue life prediction formulas for this type of turbine blade material under different working conditions can be obtained.

Specifically, referring to the previous implementation, for GH4169, only the fatigue test data set of GH4169 at 25° C. is used as the input, and the representative and excellent expressions (1)-(3) of GH4169 at 25° C. in Table 2 are output. Then, using the RMSE and the determination coefficient R² as the performance evaluation criterion, the expression (1), which has the significantly optimal fitting effect for GH4169 at 25° C., is selected as the fatigue life prediction formula for the material under this working condition:

$$ln ( {N}_{f} ) = 3.148 + \frac{7.1 \; 71 ( {ε}_{a} \frac{{τ}_{a}}{G} - 0.785 \frac{{τ}_{a}}{G} + 2.74 )}{( {ε}_{a} + {γ}_{a} ) ( {ε}_{a} \frac{{τ}_{a}}{G} - 0.785 \frac{{τ}_{a}}{G} + 2.74 ) - 0.003}$$

Its structure is retained and used as the general fatigue life prediction formula for GH4169 material:

$$ln ( {N}_{f} ) = a + \frac{b ( {ε}_{a} \frac{{τ}_{a}}{G} + c \frac{{τ}_{a}}{G} + d )}{( {ε}_{a} + {γ}_{a} ) ( {ε}_{a} \frac{{τ}_{a}}{G} + c \frac{{τ}_{a}}{G} + d ) + e}$$

wherein a, b, c, d, and e all represent constant values in the general formula, which vary with different working conditions. The L-BFGS optimization algorithm is utilized in the model to explore the optimal constant values of the expression under different working conditions, and the fatigue life prediction formula for GH4169 at 650° C. is obtained:

$$ln ( {N}_{f} ) = 0.302 + \frac{11.6 \; 25 ( {ε}_{a} \frac{{τ}_{a}}{G} + 297.975 \frac{{τ}_{a}}{G} + 185.977 )}{( {ε}_{a} + {γ}_{a} ) ( {ε}_{a} \frac{{τ}_{a}}{G} + 297.975 \frac{{τ}_{a}}{G} + 185.977 ) + 1202.181}$$

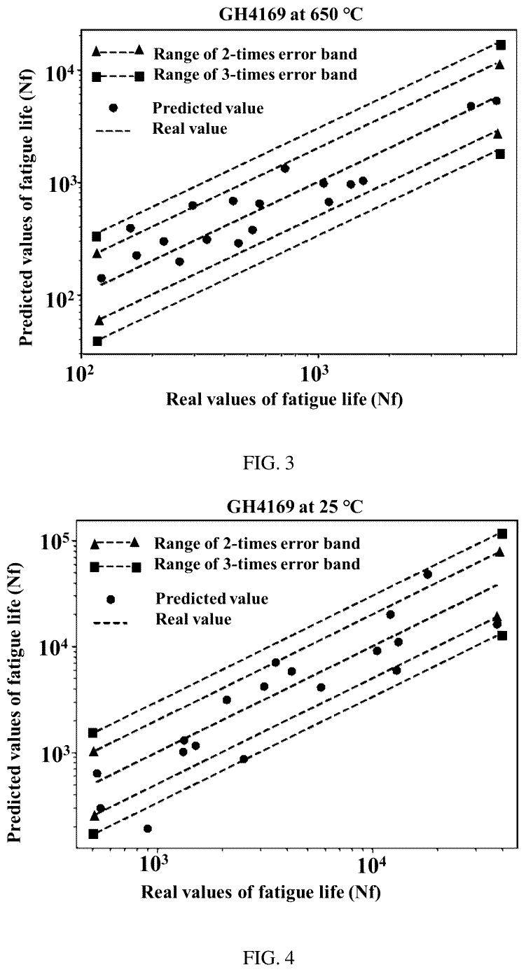

The RMSE value between the fatigue life predicted by the above-mentioned fatigue life prediction formula and the real fatigue life is 2.9413×10², and the value of R² is 0.96022. A comparison between the predicted values and the real values is shown in FIG. 2 and FIG. 3. At 25° C., all sample points of the GH4169 material fall within a range of 3-times error band, and 94.4% of the material sample points fall within a range of 2-times error band. At 650° C., all the sample points of the GH4169 material fall within the range of 3-times error band, and 88.9% of the material sample points fall within the range of 2-times error band. The results show that the prediction accuracy of the fatigue life prediction formula at 650° C. explored by this method has reached a satisfactory prediction level, that is, the prediction effect of the fatigue life prediction expressions corresponding to different working conditions explored by retaining the general expression structure is excellent.

From the above examples of fatigue life prediction formulas, it can be found that the fatigue life prediction formulas for the same material under different working conditions are structurally universal. After obtaining the optimal prediction formula for the GH4169 under a certain working condition, its structure can be retained, and the constant values of the expressions under different working conditions can be explored to obtain the fatigue life prediction formulas corresponding to different working conditions.

As shown above, a general formula for the TC4 material under different working conditions is as follows:

$$ln ( {N}_{f} ) = {a}^{′} + {b}^{′} ( \frac{{ε}_{a}}{{c}^{′} - \frac{{τ}_{a}}{G}} + \frac{{σ}_{a}}{E} ) + \frac{{d}^{′}}{{ε}_{a}}$$

wherein a′, b′, c′, and d′ all represent constant values in the general formula, which vary with different working conditions.

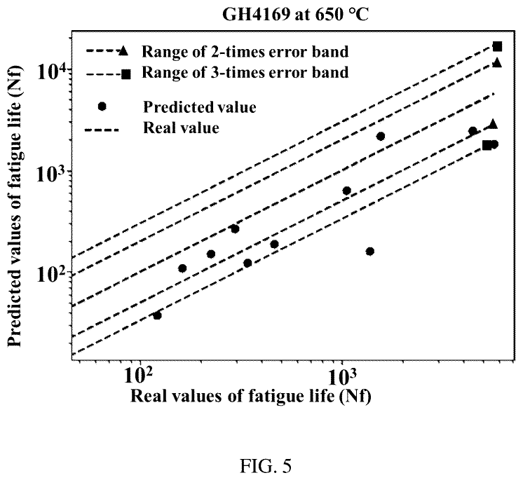

To prevent the proposed algorithm from over-fitting in the application of exploring the general expression structure, the present invention utilizes the ten-fold cross-validation method on material data to evaluate the generalization ability of the model and ensure the robustness and reliability of the model. The data set of the GH4169 at 25° C. is divided into ten parts. Each part is used as a validation set in turn to train the model, and a training set is used to explore the general expression structure. Evaluation results of the ten validation tests are integrated, as shown in FIG. 4 and FIG. 5. It is found that the trend observed in the results of the ten validation tests is consistent with the prediction results in FIG. 2 and FIG. 3. For the GH4169 at 25° C., more than 90% of the predicted data are within the range of the 2-times error band, and the RMSE value is 9.196×10³. This indicates that the generalization ability of the algorithm is robust, and it can effectively predict unknown data.

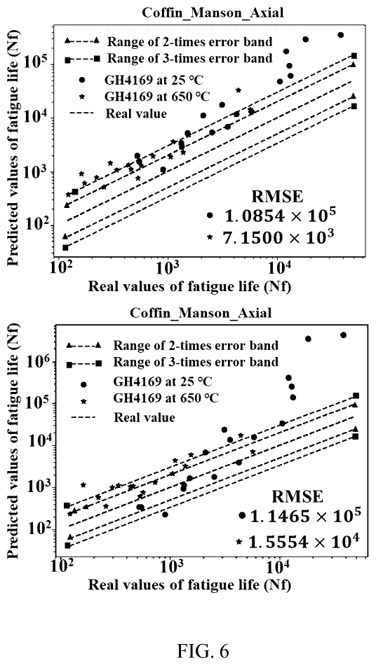

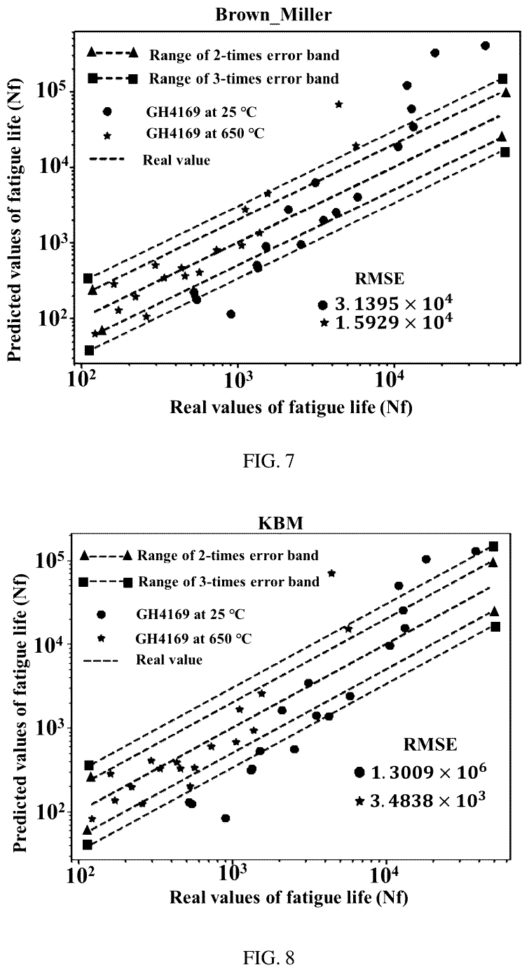

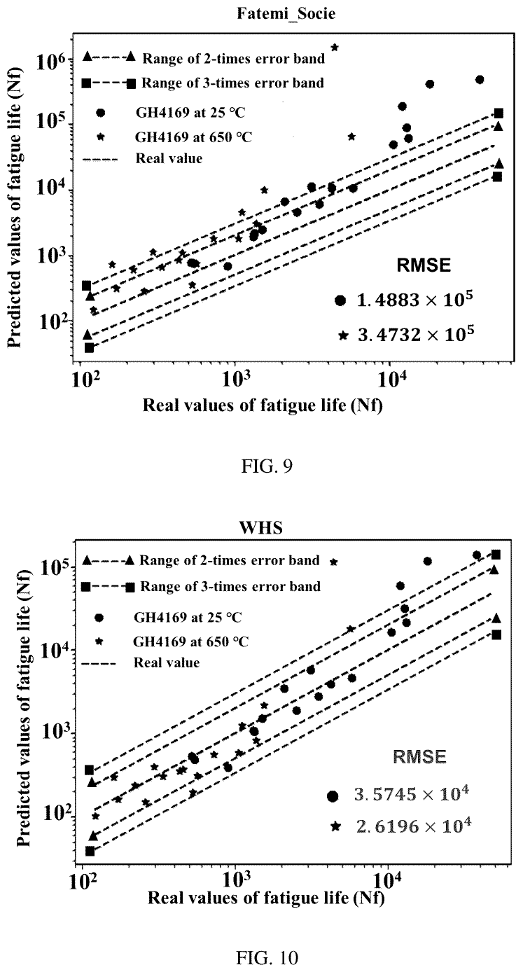

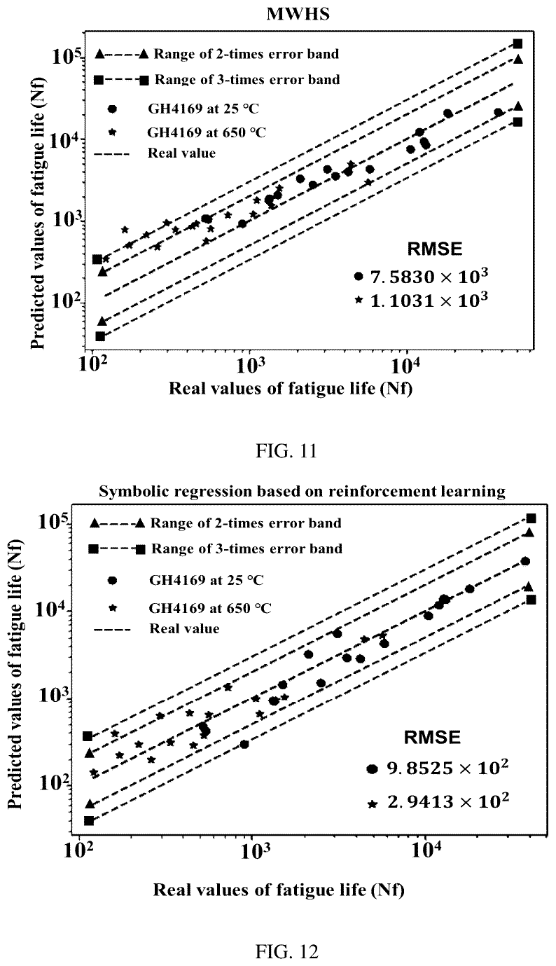

Further, the optimal fatigue life prediction formula for the GH4169 at 25° C. in the second implementation and the fatigue life prediction formula at 650° C. explored from the general structure are compared with six empirical formulas and five commonly used machine learning algorithms to verify the performance of the model. Compared with empirical formulas specifically including a Coffin Manson equation, a BM (Brown-Miller) and KBM (Kandil, Brown and Miller) models, an FS (Fatemi and Socie) model, and WHS and MWHS models, the comparison results are as shown in FIG. 6 to FIG. 12. Among all the algorithms, the RMSE and R² values of the fatigue life prediction formula proposed in the present invention perform the best, and the formula has the best prediction accuracy.

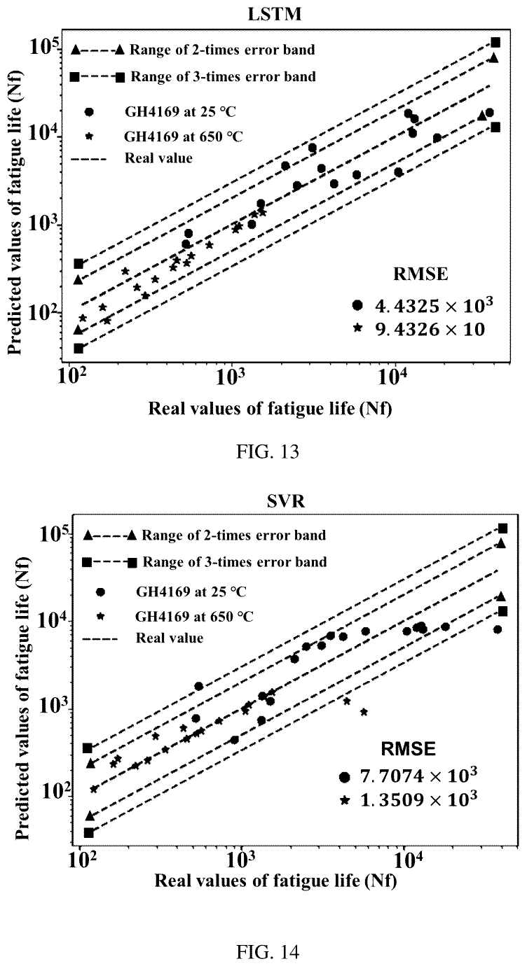

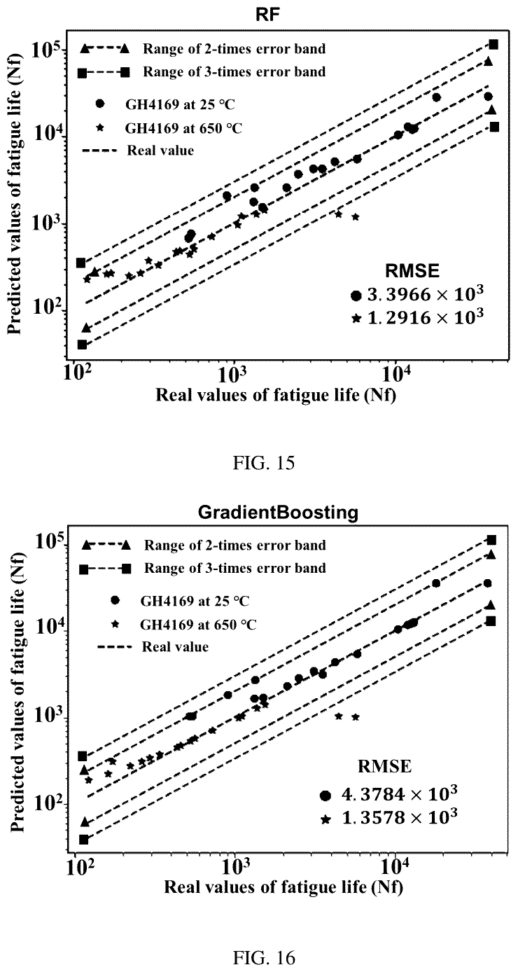

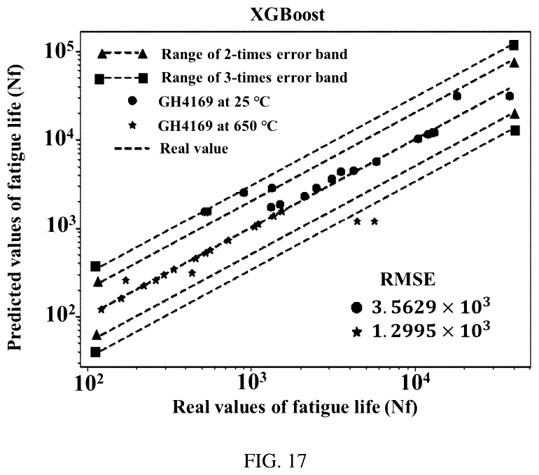

Compared with machine learning algorithms specifically including the Long Short-Term Memory (LSTM), Support Vector Regression (SVR), Random Forest (RF), Gradient Boosting, and XGBoost, the comparison results are as shown in FIG. 13 to FIG. 17. Among the algorithms participating in the comparison, the fatigue life prediction formula (FIG. 12) proposed in the present invention has achieved a prediction accuracy comparable to or even better than that of the machine learning algorithms. Compared with black-box models such as the machine learning algorithms, the method proposed in the present invention is interpretable and has stronger generalizability in a physical context.

### Step 4: Predicting the Fatigue Life of the Turbine Blade;

Taking into account the working environment of the turbine blade, the material parameters of the GH4169 at 650° C. is applied to the single blade model for COMSOL finite element simulation, and a rotation speed with cyclic symmetric variation is applied to simulate a centrifugal force, as well as the self-gravity of the blade, so as to obtain the basic mechanical performance parameters of the dangerous parts of the blade under different rotation speed working conditions, which are specifically as shown in Table 3.

TABLE 3
Basic mechanical performance of dangerous parts
of blade under different working conditions

| Operating condition | ω(rpm) | ε_{a, max}(%) | γ_{a, max}(%) | σ_{a, max}(MP [symbol] | τ_{a, max}(MP [symbol] |
|---|---|---|---|---|---|
| S1: Start -- Maximum | 0-12000-0 | 1.76 | 0.62 | 2711.1 | 854.08 |
| rotation speed -- Start | | | | | |
| S2: Start -- Cruise -- | 0-9500-0 | 1.10 | 0.39 | 1698.8 | 535.18 |
| Start | | | | | |
| S3: Minimum rotation | 8200-12000-8200 | 0.94 | 0.33 | 1445.6 | 455.42 |
| speed -- Maximum | | | | | |
| rotation speed -- | | | | | |
| Minimum rotation | | | | | |
| speed | | | | | |
| S4: Cruise -- Maximum | 9500-12000-9500 | 0.66 | 0.23 | 1012.3 | 318.9 |
| rotation speed -- Cruise | | | | | |

[symbol]

indicates data missing or illegible when filed

The basic mechanical performance parameters of the dangerous parts of the blade are taken as an input of the optimal prediction expression (7) of the GH4169 material at 650° C. in step 3 and the prediction expression explored by the general structure in the second implementation, so as to predict the number of fatigue life cycles of the blade under the corresponding working conditions. The WHS model that performed well in step 3 is taken as a representative method of the empirical formula. The prediction results of the three methods are as shown in Table 4. From the results, it can be seen that under the working conditions of S3 and S4, the predicted life value (N_{f}) of expression obtained by exploring using the general structure has little difference from the predicted life value (N_{f}′) of the optimal prediction expression, which further confirms the reliability of the general structure. The fatigue lifes predicted by empirical formula represented by the WHS and the logic constraint-enhanced symbolic regression model have the same dimension, little difference, and consistent change trend. Under the cyclic symmetric rotation speed load, the greater the variation range of the working conditions of the turbine blade, the shorter its fatigue life is.

TABLE 4
Prediction results of fatigue life of blade under different working
conditions by the enhanced symbolic regression model and WHS

| | | N_{f} | N′_{f} | N_{f} of WHS |
|---|---|---|---|---|
| Operating | | (Number | (Number | (Number |
| condition | ω(rpm) | of cycles) | of cycles) | of cycles) |
| S1 | 0-12000-0 | 107 | 1.1 × e⁻⁶ | 112 |
| S2 | 0-9500-0 | 569 | 130 | 414 |
| S3 | 8200-12000-8200 | 946 | 802 | 686 |
| S4 | 9500-12000-9500 | 2043 | 2778 | 2584 |

Through the analysis of the above examples and in combination with the comparison results with the empirical formula method and the machine learning model, the main technical contributions of the present invention are as follows: a fatigue life prediction method of a turbine blade based on logic constraint-enhanced symbolic regression is proposed. This prediction method is realized based on the novel symbolic regression model (i.e., the logic constraint-enhanced symbolic regression model) guided by the deep reinforcement learning and with the logic constraint rules. The present invention proposes the application of the logic constraint rules to optimize the search space of nodes and ensure the rationality of the generated expression structure and the effectiveness of its actual physical meaning. It is proposed to adopt the reinforcement learning guidance with the RNN as the carrier in the training of the node selection strategy to improve the generation efficiency and accuracy of high-quality expressions.

With the continuous expansion of the fatigue test data set in the future and the finite element simulation results getting closer and closer to the real fatigue failure modes, combining the algorithm proposed in the present invention with the finite element simulation can provide a reliable reference for the life prediction, maintenance and repair of key components in future engineering applications.

The descriptions of the above specification and implementation examples are used to explain the protection scope of this application. However, they are only for illustrative purposes, and the application scope of the present invention is not restrictive. Changes made without departing from the purpose of the present invention and the scope protected by the claims all fall within the protection scope of the present invention.

1. A computer-implemented method for predicting fatigue life of a turbine blade based on logic constraint-enhanced symbolic regression, wherein the method comprises the following steps:
S1: obtaining a turbine blade material fatigue test dataset including a true life value of the turbine blade material based on a turbine blade material fatigue test; constructing a symbol library based on the fatigue test dataset of the turbine blade, wherein the symbol library comprises nodes, the nodes comprising: input variables, arithmetic operators, and constants; the input variables are basic mechanical property parameters of the turbine blade, comprising: axial stress σₐ, shear stress τₐ, Young's modulus E, shear modulus G, an axial strain rate εₐ, and a shear strain rate γₐ; and the arithmetic operators comprising an addition operator, a subtraction operator, a multiplication operator, a division operator, a trigonometric function operator, and an exponential operator;
S2: performing dimensionless preprocessing on the input variables in the symbol library to obtain a preprocessed symbol library;
S3: selecting a node from the preprocessed symbol library to construct a series of expressions; and selecting an expression from the series of expressions, and outputting the selected expression with a fitting effect that is closest to a real fatigue test as a fatigue life prediction formula by obtaining a second fatigue life determined by the real fatigue test as a benchmark, wherein the selection of the node is guided by reinforcement learning with a recurrent neural network (RNN) as a carrier guides the selection of the node from the symbol library and optimization of the structure of the series of expressions, and applies a logic constraint rule in the selected node;
wherein the RNN generates a selection probability of each node in the symbol library as a selection strategy of reinforcement learning, and each selection behavior has a corresponding feedback reward value, which is related to a fitting effect of the expression; and the RNN generates the series of expressions, selects a first expression therefrom, reinforces a selection behavior related to a higher reward value than the corresponding feedback reward value of the selection behavior of the selection of the first expression, and guides subsequent series to generate second expressions; the selection process continues until the RNN independently select an appropriate node from the symbol library according to an expression state, and the RNN generates the expression with the fitting effect that is closest to the real fatigue test; and
wherein the logic constraint rule comprises: tracking the construction of the expressions by using an array, controlling a length of the expressions, and imposing a constraint on a constant operation and function nesting, wherein the logic constraint rule is applied to the selection process of each node in a form of the selection probability, and a negative infinite selection probability is applied to a node type that violates the rule; and an optimal value of a constant node is determined by using limited-memory Broyden Fletcher-Goldfarb-Shanno optimization; and
S4: performing a finite element simulation on a turbine blade model to be tested by applying cyclically symmetrically varying rotational speed to simulate centrifugal force and the blade's own weight to obtain basic mechanical property parameters of another part of the turbine blade under different working conditions, which are used as an input of the fatigue life prediction formula output in step S3, and outputting a fatigue life cycle number of the turbine blade under a corresponding working condition, so as to realize prediction of the fatigue life of the turbine blade;
wherein in the step S3, the output of the RNN is the fatigue life prediction formulas for turbine blade made of different materials under different working conditions, or
the output of the RNN is the fatigue life prediction formulas for different materials under a certain working condition; and then for turbine blades made of the same material, by taking the fatigue life prediction formulas for the different materials under the certain working condition as general structural expressions, and exploring and adjusting the constant nodes in the expressions;
wherein the output of the RNN is the fatigue life prediction formulas for different materials under the certain working condition, and for turbine blades made of GH4169 material and TC4 material, fatigue life prediction formulas are as follows:
a first general formula for the GH4169 material under different working conditions:
$$ln ( {N}_{f} ) = a + \frac{b ( {ε}_{a} \frac{{τ}_{a}}{G} + c \frac{{τ}_{a}}{G} + d )}{( {ε}_{a} + {γ}_{a} ) ( {ε}_{a} \frac{{τ}_{a}}{G} + c \frac{{τ}_{a}}{G} + d ) + e}$$
a second general formula for the TC4 material under different working conditions:
$$ln ( {N}_{f} ) = {a}^{′} + {b}^{′} ( \frac{{ε}_{a}}{{c}^{′} - \frac{{τ}_{a}}{G}} + \frac{{σ}_{a}}{E} ) + \frac{{d}^{′}}{{ε}_{a}}$$
wherein a, b, c, d, e, a′, b′, c′, and d′ all represent constant values in the first and second general formulas, which vary with different working conditions;
σₐ/E physically represents the axial strain, τₐ/G represents the shear strain, N_{f} is the number of fatigue life cycles.

2. The method according to claim 1, wherein in the step S2, performing dimensionless preprocessing on the input variables in the symbol library is conducted by performing a symbolic operation among input variables with physical units, and transforming the input variables into σₐ/E, τₐ/G, εₐ and γₐ after the dimensionless preprocessing.

3. The method according to claim 1, wherein
the tracking the construction of the expressions by using the array comprises: adopting a binary tree structure by the expression, and using the array to track a suspension situation of tree structure nodes; each time an arithmetic operator node is added, putting a number of child nodes that needs to be suspended in the node into the array; each time the input variables or the constant nodes are added, decreasing the number of the child nodes at the end of the array by one, wherein this process is repeated until the array is empty, indicating that the construction of the expressions is completed;
controlling a length of the expressions comprises: constraining the length of the expressions by limiting the number of arithmetic operator nodes;
imposing the constraint on a constant operation comprises: constraining the number of the constant nodes, and restricting a constant arithmetic operation; and
imposing the constraint on function nesting comprises: constraining a nesting operation of unary functions.

4-5. (canceled)

6. A device for predicting fatigue life of a turbine blade based on logic constraint-enhanced symbolic regression, comprising a memory and one or more processors, wherein the memory stores executable codes, and when being executed by the one or more processors, the executable codes are used to implement the f method according to claim 1.

7. A non-transitory computer-readable storage medium having a program stored thereon, wherein when being executed by a processor, the program is used to implement the method according to claim 1.
